(19) United States
(12) Patent Application Publication
(10) Pub. No.: US 2026/0051864 A1
(43) Pub. Date: Feb. 19, 2026

(54) COMPACT INTEGRATION OF STACKED POWER AMPLIFIER DESIGNS

(71) Applicant: SKYWORKS SOLUTIONS, INC., Irvine, CA (US)

(72) Inventors: Hailing Wang, Acton, MA (US); John Jackson Nisbet, Ottawa (CA); Michael Joseph McPartlin, North Andover, MA (US); Guillaume Alexandre Blin, Carlisle, MA (US)

(21) Appl. No.: 19/291,794

(22) Filed: Aug. 6, 2025

Related U.S. Application Data
(60) Provisional application No. 63/682,494, filed on Aug. 13, 2024.

(51) Int. Cl. H03F 3/24; H01L 23/66; H03F 1/22

(52) U.S. Cl. CPC H03F 3/245; H01L 23/66; H03F 1/223; H01L 2223/6611; H03F 2200/451

(57) ABSTRACT

Aspects and embodiments disclosed herein include a stacked power amplifier cell comprising an active diffusion layer deposited on a substrate, a first series transistor including a first source electrode, a first drain electrode, and a first gate contact mounted on the active diffusion layer, and a second series transistor including a second source electrode, a second drain electrode, and a second gate contact mounted on the active diffusion layer, the second source electrode being electrically connected to the first drain electrode and a thickness of the second gate oxide layer being greater than a thickness of the first gate oxide layer.

### CROSS-REFERENCE TO RELATED APPLICATIONS

This application claims priority under 35 U.S.C. § 119(e) to U.S. Provisional Patent Application Ser. No. 63/682,494, titled “COMPACT INTEGRATION OF STACKED POWER AMPLIFIER DESIGNS,” filed Aug. 13, 2024, the entire content of which is incorporated herein by reference for all purposes.

### BACKGROUND

### Field

Embodiments of this disclosure relate to radio frequency electronic systems, such as front end systems and related devices, integrated circuits, and modules.

### Description of Related Technology

A radio frequency electronic system can process radio frequency (RF) signals in a frequency range from about 30 kilohertz (kHz) to 300 gigahertz (GHz), such as in a range from about 450 megahertz (MHz) to 7.125 GHz. A front end system is an example of a radio frequency electronic system. A front end system can be referred to as an RF front end (RFFE) system. A front end system can process signals being transmitted and/or received via one or more antennas. For example, a front end system can include one or more switches, one or more filters, one or more low noise amplifiers, one or more power amplifiers, other circuitry, or any suitable combination thereof in one or more signal paths between one or more antennas and a transceiver. Front end systems can include one or more receive paths and one or more transmit paths.

A front-end system can include a power amplifier in a transmit path. Power amplifiers can be included in front-end systems in a wide variety of communications devices to amplify an RF signal for transmission. An RF signal amplified by a power amplifier can be transmitted via an antenna. Example communications devices having power amplifiers include, but are not limited to, Internet of Things (IoT) devices, mobile phones, tablets, base stations, network access points, laptops, computers, and televisions. As an example, in mobile phones that communicate using a cellular standard, a wireless local area network (WLAN) standard, and/or any other suitable communication standard, a power amplifier can be used to amplify the RF signal.

Some RF power amplifiers are implemented in a semiconductor-on-insulator process technology, such as a silicon-on-insulator (SOI) complementary metal oxide semiconductor (CMOS) process technology. CMOS process technology provides for a low-cost solution to integrate RF, digital, and analog functions into a single chip. In RFFE modules good performance has already been achieved for the switches and the low noise amplifiers using CMOS technologies. RF power amplifiers in CMOS process technology, however, still present challenges for fully integrated front-end-module designs, mainly due to their relatively low breakdown voltage as well as their low power density inherent to the nature of CMOS manufacturing.

### SUMMARY

In certain embodiments, the present disclosure relates to a stacked power amplifier cell. The stacked power amplifier cell includes a substrate and an active diffusion layer deposited on the substrate. The stacked power amplifier cell further includes a first series transistor and a second series transistor. The first series transistor includes a first source electrode, a first drain electrode, and a first gate contact mounted on the active diffusion layer. The first gate contact includes a first gate oxide layer deposited on the active diffusion layer, a first gate polysilicon layer arranged on the first gate oxide layer, and a first gate electrode deposited on the first gate polysilicon layer. The second series transistor includes a second source electrode, a second drain electrode, and a second gate contact mounted on the active diffusion layer. The second gate contact includes a second gate oxide layer deposited on the active diffusion layer, a second gate polysilicon layer arranged on the second gate oxide layer, and a second gate electrode deposited on the second gate polysilicon layer. The second source electrode is electrically connected to the first drain electrode. A thickness of the second gate oxide layer is greater than a thickness of the first gate oxide layer.

According to several embodiments, the first source electrode is electrically connected to a ground potential and the second drain electrode is electrically connected to a supply potential. In some embodiments, the stacked power amplifier cell further includes a first gate feed strip deposited on the substrate and electrically connected to the first gate electrode. According to a number of embodiments, the stacked power amplifier cell further includes an integrated resistor coupled between the first gate electrode and the first gate feed strip. In various embodiments, the first gate feed strip extends in parallel to the first gate electrode. According to some embodiments, the stacked power amplifier cell further includes a drain contact metallization layer formed over the second drain electrode, the drain contact metallization layer extending in parallel to the first gate feed strip.

In various embodiments, the first series transistor includes a third gate contact mounted on the active diffusion layer adjacent to the first gate contact. The third gate contact includes a third gate oxide layer deposited on the active diffusion layer, a third gate polysilicon layer arranged on the third gate oxide layer, and a third gate electrode deposited on the third gate polysilicon layer. According to some embodiments, a thickness of the third gate oxide layer is substantially equal to the thickness of the first gate oxide layer. In a few embodiments, the stacked power amplifier cell further includes a second gate feed strip deposited on the substrate and electrically connected to the third gate electrode. According to various embodiments, the second gate feed strip extends perpendicular to the third gate electrode.

In a few embodiments, the stacked power amplifier cell further includes a source contact metallization layer formed over the first source electrode, the source contact metallization layer being connected to ground potential. In several embodiments, the stacked power amplifier cell further includes a redistribution layer formed over the source contact metallization layer.

In certain other embodiments, the present disclosure relates to a stacked power amplifier cell. The stacked power amplifier cell includes a substrate and an active diffusion layer deposited on the substrate. The active diffusion layer includes a first active diffusion region having a first thickness and a second active diffusion region having a second thickness, the second thickness being greater than the first thickness. The stacked power amplifier cell further includes a first series transistor and a second series transistor. The first series transistor includes a first source electrode, a first drain electrode, and a first gate contact mounted on the first active diffusion region. The first gate contact includes a first gate oxide layer deposited on the first active diffusion region, a first gate polysilicon layer arranged on the first gate oxide layer, and a first gate electrode deposited on the first gate polysilicon layer. The second series transistor includes a second source electrode, a second drain electrode, and a second gate contact mounted on the second active diffusion region. The second gate contact includes a second gate oxide layer deposited on the second active diffusion region, a second gate polysilicon layer arranged on the second gate oxide layer, and a second gate electrode deposited on the second gate polysilicon layer. The second source electrode is electrically connected to the first drain electrode.

According to various embodiments, the first source electrode is electrically connected to a ground potential and the second drain electrode is electrically connected to a supply potential. In some embodiments, the stacked power amplifier cell further includes a first gate feed strip deposited on the substrate and electrically connected to the first gate electrode. In a number of embodiments, the stacked power amplifier cell further includes an integrated resistor coupled between the first gate electrode and the first gate feed strip. According to a few embodiments, the first gate feed strip extends in parallel to the first gate electrode. According to various embodiments, the stacked power amplifier cell further includes a drain contact metallization layer formed over the second drain electrode, the drain contact metallization layer extending in parallel to the first gate feed strip.

According to a few embodiments, the first series transistor includes a third gate contact mounted on the first active diffusion region adjacent to the first gate contact. The third gate contact includes a third gate oxide layer deposited on the first active diffusion region, a third gate polysilicon layer arranged on the third gate oxide layer, and a third gate electrode deposited on the third gate polysilicon layer. In a number of embodiments, the stacked power amplifier cell further includes a second gate feed strip deposited on the substrate and electrically connected to the third gate electrode. In several embodiments, the second gate feed strip extends perpendicular to the third gate electrode.

According to a number of embodiments, the stacked power amplifier cell further includes a source contact metallization layer formed over the first source electrode, the source contact metallization layer being connected to ground potential. In a few embodiments, the stacked power amplifier cell further includes a redistribution layer formed over the source contact metallization layer.

In certain other embodiments, the present disclosure relates to a radio-frequency (RF) module. The RF module includes a packaging substrate configured to receive a plurality of components and a power amplification system implemented on the packaging substrate. The power amplification system includes a stacked power amplifier (PA) cell configured to receive and amplify an RF signal. The stacked PA cell includes a substrate and an active diffusion layer deposited on the substrate. The stacked PA cell further includes a first series transistor and a second series transistor. The first series transistor includes a first source electrode, a first drain electrode, and a first gate contact mounted on the active diffusion layer. The first gate contact includes a first gate oxide layer deposited on the active diffusion layer, a first gate polysilicon layer arranged on the first gate oxide layer, and a first gate electrode deposited on the first gate polysilicon layer. The second series transistor includes a second source electrode, a second drain electrode, and a second gate contact mounted on the active diffusion layer. The second gate contact includes a second gate oxide layer deposited on the active diffusion layer, a second gate polysilicon layer arranged on the second gate oxide layer, and a second gate electrode deposited on the second gate polysilicon layer. The second source electrode is electrically connected to the first drain electrode. A thickness of the second gate oxide layer is greater than a thickness of the first gate oxide layer.

In some embodiments, the first source electrode is electrically connected to a ground potential and the second drain electrode is electrically connected to a supply potential.

In some embodiments, the stacked PA cell further includes a first gate feed strip deposited on the substrate and electrically connected to the first gate electrode.

In some embodiments, the stacked PA cell further includes an integrated resistor coupled between the first gate electrode and the first gate feed strip. The first gate feed strip may extend in parallel to the first gate electrode. The stacked PA cell may further include a drain contact metallization layer formed over the second drain electrode, the drain contact metallization layer extending in parallel to the first gate feed strip.

In some embodiments, the first series transistor includes a third gate contact mounted on the active diffusion layer adjacent to the first gate contact, the third gate contact including a third gate oxide layer deposited on the active diffusion layer, a third gate polysilicon layer arranged on the third gate oxide layer, and a third gate electrode deposited on the third gate polysilicon layer. A thickness of the third gate oxide layer may be substantially equal to the thickness of the first gate oxide layer. The stacked PA cell may further include a second gate feed strip deposited on the substrate and electrically connected to the third gate electrode. The second gate feed strip may extend perpendicular to the third gate electrode.

In some embodiments, the stacked PA cell further includes a source contact metallization layer formed over the first source electrode, the source contact metallization layer being connected to ground potential. The stacked PA cell may further include a redistribution layer formed over the source contact metallization layer.

In certain other embodiments, the present disclosure relates to a radio-frequency (RF) module. The RF module includes a packaging substrate configured to receive a plurality of components and a power amplification system implemented on the packaging substrate. The power amplification system includes a stacked power amplifier (PA) cell configured to receive and amplify an RF signal. The stacked PA cell includes a substrate and an active diffusion layer deposited on the substrate. The active diffusion layer includes a first active diffusion region having a first thickness and a second active diffusion region having a second thickness, the second thickness being greater than the first thickness. The stacked PA cell further includes a first series transistor and a second series transistor. The first series transistor includes a first source electrode, a first drain electrode, and a first gate contact mounted on the first active diffusion region. The first gate contact includes a first gate oxide layer deposited on the first active diffusion region, a first gate polysilicon layer arranged on the first gate oxide layer, and a first gate electrode deposited on the first gate polysilicon layer. The second series transistor includes a second source electrode, a second drain electrode, and a second gate contact mounted on the second active diffusion region. The second gate contact includes a second gate oxide layer deposited on the second active diffusion region, a second gate polysilicon layer arranged on the second gate oxide layer, and a second gate electrode deposited on the second gate polysilicon layer. The second source electrode is electrically connected to the first drain electrode.

In some embodiments, the first source electrode is electrically connected to a ground potential and the second drain electrode is electrically connected to a supply potential.

In some embodiments, the stacked PA cell further includes a first gate feed strip deposited on the substrate and electrically connected to the first gate electrode. The stacked PA cell may further include an integrated resistor coupled between the first gate electrode and the first gate feed strip. The first gate feed strip may extend in parallel to the first gate electrode. The stacked PA cell may further include a drain contact metallization layer formed over the second drain electrode, the drain contact metallization layer extending in parallel to the first gate feed strip.

In some embodiments, the first series transistor includes a third gate contact mounted on the first active diffusion region adjacent to the first gate contact, the third gate contact including a third gate oxide layer deposited on the first active diffusion region, a third gate polysilicon layer arranged on the third gate oxide layer, and a third gate electrode deposited on the third gate polysilicon layer. The stacked PA cell may further include a second gate feed strip deposited on the substrate and electrically connected to the third gate electrode. The second gate feed strip may extend perpendicular to the third gate electrode.

In some embodiments, the stacked PA cell further includes a source contact metallization layer formed over the first source electrode, the source contact metallization layer being connected to ground potential. The stacked PA cell may further include a redistribution layer formed over the source contact metallization layer.

In certain other embodiments, the present disclosure relates to a radio-frequency (RF) device. The RF device includes a transceiver configured to generate an RF signal and a front-end module (FEM) in communication with the transceiver. The FEM includes a packaging substrate configured to receive a plurality of components, and a stacked power amplifier (PA) implemented on the packaging substrate and configured to amplify the RF signal. The stacked PA includes a substrate and an active diffusion layer deposited on the substrate. The stacked PA further includes a first series transistor and a second series transistor. The first series transistor includes a first source electrode, a first drain electrode, and a first gate contact mounted on the active diffusion layer. The first gate contact includes a first gate oxide layer deposited on the active diffusion layer, a first gate polysilicon layer arranged on the first gate oxide layer, and a first gate electrode deposited on the first gate polysilicon layer. The second series transistor includes a second source electrode, a second drain electrode, and a second gate contact mounted on the active diffusion layer. The second gate contact includes a second gate oxide layer deposited on the active diffusion layer, a second gate polysilicon layer arranged on the second gate oxide layer, and a second gate electrode deposited on the second gate polysilicon layer. The second source electrode is electrically connected to the first drain electrode. A thickness of the second gate oxide layer is greater than a thickness of the first gate oxide layer.

In certain other embodiments, the present disclosure relates to a radio-frequency (RF) device. The RF device includes a transceiver configured to generate an RF signal and a front-end module (FEM) in communication with the transceiver. The FEM includes a packaging substrate configured to receive a plurality of components, and a stacked power amplifier (PA) implemented on the packaging substrate and configured to amplify the RF signal. The stacked PA includes a substrate and an active diffusion layer deposited on the substrate. The active diffusion layer includes a first active diffusion region having a first thickness and a second active diffusion region having a second thickness, the second thickness being greater than the first thickness. The stacked PA further includes a first series transistor and a second series transistor. The first series transistor includes a first source electrode, a first drain electrode, and a first gate contact mounted on the first active diffusion region. The first gate contact includes a first gate oxide layer deposited on the first active diffusion region, a first gate polysilicon layer arranged on the first gate oxide layer, and a first gate electrode deposited on the first gate polysilicon layer. The second series transistor includes a second source electrode, a second drain electrode, and a second gate contact mounted on the second active diffusion region. The second gate contact includes a second gate oxide layer deposited on the second active diffusion region, a second gate polysilicon layer arranged on the second gate oxide layer, and a second gate electrode deposited on the second gate polysilicon layer. The second source electrode is electrically connected to the first drain electrode. An antenna is in communication with the FEM and is configured to transmit the amplified RF signal.

In certain other embodiments, the present disclosure relates to an array of stacked power amplifier (PA) cells. The array includes a common substrate, an active diffusion layer deposited on the common substrate, and a plurality of stacked PA cells arranged adjacently on the common substrate. Each of the stacked PA cells includes a first series transistor and a second series transistor. Each of the first series transistors includes a first source electrode, a first drain electrode, and a first gate contact mounted on the active diffusion layer. The first gate contact includes a first gate oxide layer deposited on the active diffusion layer, a first gate polysilicon layer arranged on the first gate oxide layer, and a first gate electrode deposited on the first gate polysilicon layer. Each of the second series transistors includes a second source electrode, a second drain electrode, and a second gate contact mounted on the active diffusion layer. The second gate contact includes a second gate oxide layer deposited on the active diffusion layer, a second gate polysilicon layer arranged on the second gate oxide layer, and a second gate electrode deposited on the second gate polysilicon layer. Each of the second source electrodes is electrically connected to a corresponding one of the first drain electrodes. A thickness of the second gate oxide layer is greater than a thickness of the first gate oxide layer. The plurality of stacked PA cells are connected in a daisy-chain by coupling the second drain electrode of one of the stacked PA cells to the first source electrode of an adjacent one of the stacked PA cells. The array further includes an antenna in communication with the FEM, the antenna configured to transmit the amplified RF signal. A first gate capacitor may be integrated on the common substrate and coupled to the first gate contacts of each of the plurality of stacked PA cells.

In several embodiments, the first series transistor of each of the plurality of stacked PA cells includes a third gate contact mounted on the active diffusion layer adjacent to the first gate contact. The third gate contact includes a third gate oxide layer deposited on the active diffusion layer, a third gate polysilicon layer arranged on the third gate oxide layer, and a third gate electrode deposited on the third gate polysilicon layer. A thickness of the third gate oxide layer is substantially equal to the thickness of the first gate oxide layer. In a few embodiments, the array further includes a second gate capacitor integrated on the common substrate and coupled to the third gate contacts of each of the plurality of stacked PA cells.

In certain other embodiments, the present disclosure relates to an array of stacked power amplifier (PA) cells. The array includes a common substrate, an active diffusion layer deposited on the common substrate, and a plurality of stacked PA cells arranged adjacently on the common substrate. The active diffusion layer includes a first active diffusion region having a first thickness and a second active diffusion region having a second thickness, the second thickness being greater than the first thickness. Each of the stacked PA cells includes a first series transistor and a second series transistor. Each of the first series transistors includes a first source electrode, a first drain electrode, and a first gate contact mounted on the first active diffusion region. The first gate contact includes a first gate oxide layer deposited on the first active diffusion region, a first gate polysilicon layer arranged on the first gate oxide layer, and a first gate electrode deposited on the first gate polysilicon layer. Each of the second series transistors includes a second source electrode, a second drain electrode, and a second gate contact mounted on the second active diffusion region. The second gate contact includes a second gate oxide layer deposited on the second active diffusion region, a second gate polysilicon layer arranged on the second gate oxide layer, and a second gate electrode deposited on the second gate polysilicon layer. Each of the second source electrodes is electrically connected to a corresponding one of the first drain electrodes. The plurality of stacked PA cells are connected in a daisy-chain by coupling the second drain electrode of one of the stacked PA cells to the first source electrode of an adjacent one of the stacked PA cells. The array further includes a first gate capacitor integrated on the common substrate and coupled to the first gate contacts of each of the plurality of stacked PA cells.

According to a number of embodiments, the first series transistor of each of the plurality of stacked PA cells includes a third gate contact mounted on the first active diffusion region adjacent to the first gate contact. The third gate contact includes a third gate oxide layer deposited on the first active diffusion region, a third gate polysilicon layer arranged on the third gate oxide layer, and a third gate electrode deposited on the third gate polysilicon layer. In some embodiments, the array further includes a second gate capacitor integrated on the common substrate and coupled to the third gate contacts of each of the plurality of stacked PA cells.

In some embodiments, The array of stacked PA cells further comprises a second gate capacitor integrated on the common substrate and coupled to the third gate contacts of each of the plurality of stacked PA cells.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1 illustrates a schematic block diagram of one example of a front end system.

FIG. 2 illustrates a schematic block diagram of another example of a front end system.

FIG. 3 depicts an example of a mobile device including a radio frequency module having a semiconductor-on-insulator die.

FIG. 4 illustrates an example FET device implemented as an individual SOI unit.

FIG. 5 illustrates a plurality of individual SOI devices similar to the example SOI device of FIG. 4.

FIGS. 6A and 6B illustrate side sectional and plan views of an example SOI FET device having an active FET implemented over a substrate such as a silicon substrate associated with a handle wafer.

FIG. 7A illustrates a top view of some layers in a stacked power amplifier cell according to one embodiment.

FIG. 7B shows the functional electric circuit equivalent of the stacked power amplifier cell as illustrated in FIG. 7A.

FIG. 8A illustrates a top view of some layers in a stacked power amplifier cell according to another embodiment.

FIG. 8B shows a schematic detail view of the part labelled with 8B in the stacked power amplifier cell illustrated in FIG. 8A.

FIG. 9 illustrates a top view of some layers in an array of stacked power amplifier cells according to yet another embodiment.

FIG. 10 shows a simplified illustration of an array of stacked power amplifier cells according to yet another embodiment.

FIG. 11 shows a simplified illustration of an array of stacked power amplifier cells according to yet another embodiment.

FIG. 12A is a schematic diagram of one embodiment of a packaged module.

FIG. 12B is a schematic diagram of a cross-section of the packaged module of FIG. 12A taken along the lines 12B-12B.

FIG. 13A illustrates a schematic block diagram of one example of a radio frequency system.

FIG. 13B illustrates a schematic block diagram of another example of a radio frequency system.

FIG. 13C illustrates a schematic block diagram of another example of a radio frequency system.

FIG. 13D illustrates a schematic block diagram of another example of a radio frequency system.

FIG. 14A is a schematic diagram of one example of a wireless communication device.

FIG. 14B is a schematic diagram of another example of a wireless communication device.

FIG. 14C is a schematic diagram of another example of a wireless communication device.

FIG. 15 is a schematic diagram of an example of a radio frequency module according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings in which like reference numerals can indicate identical or functionally similar elements.

It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### Front End Systems

A front end system can be used to handle signals being transmitted and/or received via one or more antennas. For example, a front end system can include switches, filters, amplifiers, and/or other circuitry in signal paths between one or more antennas and a transceiver.

Implementing one or more features described herein in a front end system can achieve a number of advantages, including, but not limited to, one or more of higher power added efficiency (PAE), better voltage balance, more compact layout, lower cost, higher linearity, superior robustness to overstress, improved stability of operation under RF load, better thermal management, superior scalability, and/or enhanced integration. Moreover, implementing one or more features described herein in a front end system can achieve desirable figure of merit (FOM) and/or other metrics by which front end systems are rated. Although some features are described herein in connection with front end systems for illustrative purposes, it will be understood that the principles and advantages described herein can be applied to a wide variety of other electronics.

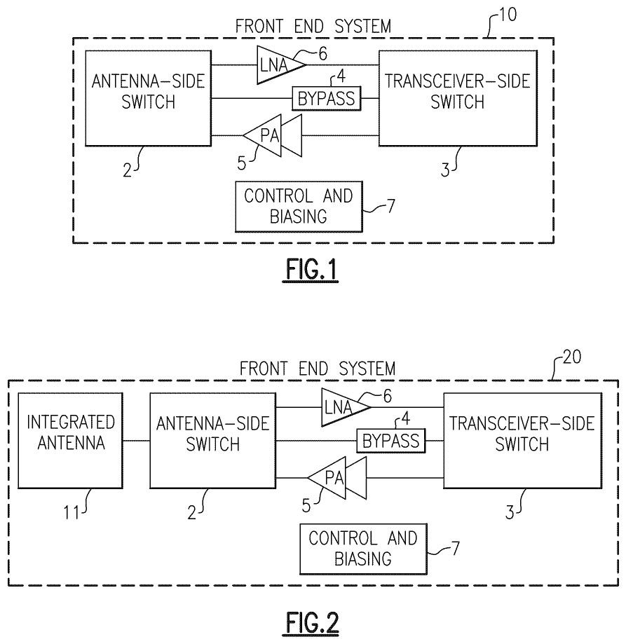

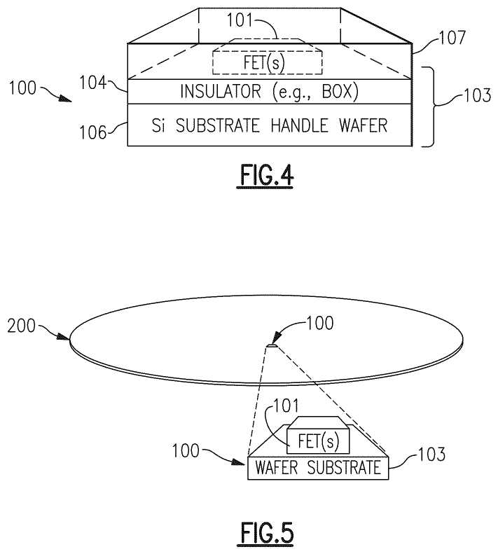

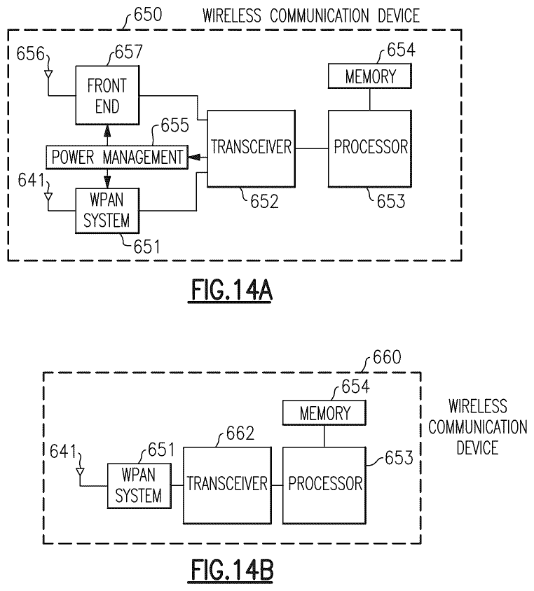

FIG. 1 illustrates a schematic block diagram of one example of a front end system 10. The front end system 10 includes an antenna-side switch 2, a transceiver-side switch 3, a bypass circuit 4, a power amplifier 5, an output matching network 9 (not shown in FIG. 1 but depicted in FIGS. 3 and 13A-D) connected to an output of the power amplifier 5, a low noise amplifier (LNA) 6, and a control and biasing circuit 7. The front end system 10 can incorporate one or more features described in the sections herein.

Although one example of a front end system is shown in FIG. 1, a front end system can be adapted in a wide variety of ways. For example, a front end system can include more or fewer components and/or signals paths. Accordingly, the teachings herein are applicable to front end systems implemented in a wide variety of ways.

In certain implementations, a front end system, such as the front end system 10 of FIG. 1, is implemented on an integrated circuit or semiconductor die. In such implementations, the front end system can be referred to as a front end integrated circuit (FEIC). In other implementations, a front end system is implemented as a module. In such implementations, the front end system can be referred to as a front end module (FEM).

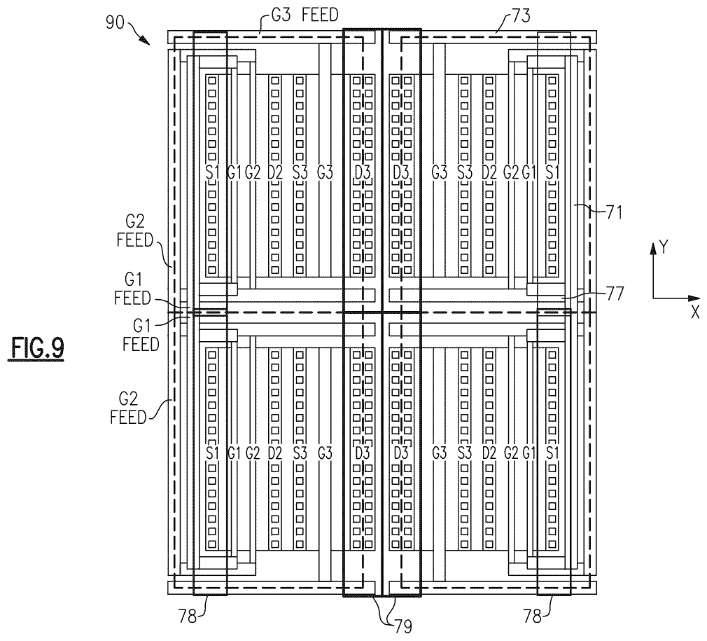

Accordingly, in some implementations, the front end system 10 is implemented in a packaged module. Such packaged modules can include a relatively low cost laminate and one or more dies that combine low noise amplifiers with power amplifiers and/or switch functions. Some such packaged modules can be multi-chip modules. In certain implementations, some or all of the illustrated components of the front end system 10 can be embodied on a single integrated circuit or die. Such a die can be manufactured using any suitable process technology. As one example, the die can be a semiconductor-on-insulator die, such as a silicon-on-insulator (SOI) die, and the power amplifier 5 can include stacked field effect complementary metal oxide (CMOS) transistors. The power amplifier 5 can be implemented in a wide variety of ways, including, but not limited to, as a stacked power amplifier design as illustrated in and explained in conjunction with FIGS. 7A, 7B, 8A, 8B, 9, 10, and 11 hereinbelow.

Using silicon-on-insulator or other semiconductor-on-insulator technology and stacked transistor topologies can enable power amplifiers to be implemented in relatively inexpensive and relatively reliable technology. Moreover, the desirable performance of low-noise amplifiers (LNAs) and/or multi-throw RF switches in silicon-on-insulator technology can enable a stacked transistor silicon-on-insulator power amplifier to be implemented as part of a complete front end integrated circuit (FEIC) solution that includes transmit, receive, and switching functionality with desirable performance

As shown in FIG. 1, the front end system 10 includes multiple signal paths between the antenna-side switch 2 and the transceiver-side switch 3. For example, the illustrated front end system 10 includes a bypass signal path that includes the bypass circuit 4, a transmit signal path that includes the power amplifier 5, and a receive signal path that includes the LNA 6. Although an example with three signal paths is shown, a front end system can include more or fewer signal paths.

The antenna-side switch 2 is used to control connection of the signal paths to an antenna (not shown in FIG. 1). For example, the antenna-side switch 2 can be used to connect a particular one of the transmit signal path, the receive signal path, or the bypass signal path to an antenna. Additionally, the transceiver-side switch 3 is used to control connection of the signal paths to a transceiver (not shown in FIG. 1). For example, the transceiver-side switch 3 can be used to connect a particular one of the transmit signal path, the receive signal path, or the bypass signal path to a transceiver. In certain implementations, the antenna-side switch 2 and/or the transceiver-side switch 3 are implemented as multi-throw switches.

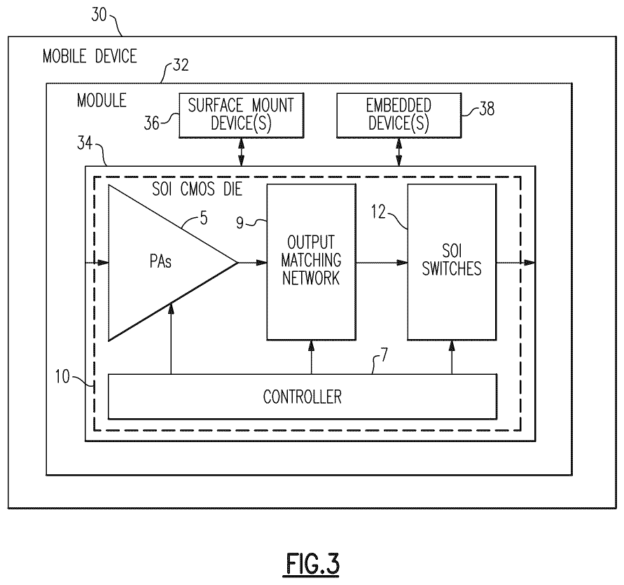

FIG. 2 illustrates a schematic block diagram of another example of a front end system 20. The front end system 20 of FIG. 2 is similar to the front end system 10 of FIG. 1, except that the front end system 20 further includes an integrated antenna 11. In some implementations, the front end system 20 can be implemented in a module along with one or more integrated antennas 11.

With reference to FIGS. 1 and 2, the bypass network 4 can include any suitable network for matching and/or bypassing the receive signal path and the transmit signal path. The bypass network 4 can be implemented, for instance, by a passive impedance network or by a conductive trace or wire. The power amplifier 5 can be used to amplify a transmit signal received from a transceiver for transmission via an antenna. The power amplifier 5 can be implemented in a wide variety of ways, including, but not limited to, as a stacked power amplifier design as illustrated in and explained in conjunction with FIGS. 7A, 7B, 8A, 8B, 9, 10, and 11 hereinbelow.

In certain implementations, the power amplifier 5 is a class F amplifier including two field-effect transistors implemented in a cascode arrangement (see, e.g., FIGS. 7A and 7B). Such a stacked power amplifier topology can be advantageous in semiconductor-on-insulator process technologies. For instance, device stacking for silicon-on-insulator power amplifier circuit topologies can overcome relatively low breakdown voltages of scaled transistors. Such device stacking can be beneficial in applications in which a stacked amplifier is exposed to a relatively large voltage swing, such as a voltage swing exceeding about 2.75 Volts. Stacking several transistors, such as 2, 3, 4 or more transistors, can result in a power amplifier with desirable operating characteristics.

In additional embodiments, the power amplifier 5 can include a stacked output stage and a bias circuit that biases the stacked transistors of the stacked output stage based on mode. In one example, the bias circuit can bias a transistor in a stack to a linear region of operation in a first mode, and bias the transistor as a switch in a second mode. Accordingly, the bias circuit can bias the stacked output stage such that the stacked output stage behaves like there are fewer transistors in the stack in the second mode relative to the first mode. Such operation can result in meeting design specifications for different power modes, in which a supply voltage provided to the stacked output stage changes based on mode.

In certain implementations, the power amplifier 5 can include a driver stage implemented using an injection-locked oscillator and an output stage having an adjustable supply voltage that changes with a mode of the power amplifier 5. By implementing the power amplifier 5 in this manner, the power amplifier 5 exhibits excellent efficiency, including in a low power mode. For example, in the low power mode, the adjustable supply voltage used to power the output stage is decreased, and the driver stage has a relatively large impact on overall efficiency of the power amplifier 5. By implementing the power amplifier 5 in this manner, the power amplifier's efficiency can be enhanced, particularly in applications in which the power amplifier's output stage operates with large differences in supply voltage in different modes of operation.

The LNA 6 can be used to amplify a received signal from the antenna. The LNA 6 can be implemented in a wide variety of ways. In some embodiments, the LNA 6 is implemented with magnetic coupling between a degeneration inductor (e.g., a source degeneration inductor or an emitter degeneration inductor) and a series input inductor. These magnetically coupled inductors can in effect provide a transformer, with a primary winding in series with the input and a secondary winding electrically connected where the degeneration inductor is electrically connected to the amplifying device (e.g., at the source of a field effect transistor amplifying device or at the emitter of a bipolar transistor amplifying device). Providing magnetically coupled inductors in this manner allows the input match inductor to have a relatively low inductance value and corresponding small size. Moreover, negative feedback provided by the magnetically coupled inductors can provide increased linearity to the LNA 6.

With continuing reference to FIGS. 1 and 2, the control and biasing circuit 7 can be used to control and bias various front end circuitry. For example, the control and biasing circuit 7 can receive control signal(s) for controlling the LNA 6, the antenna-side switch 2, the transceiver-side switch 3, and/or the power amplifier 5. The control signals can be provided to the control and biasing circuit 7 in a variety of ways, such as over an input pad of a die. In one example, the control signals include at least one of a mode signal or a bias control signal.

The front end system 10 of FIG. 1 and the front end system 20 of FIG. 2 can be implemented on one or more semiconductor dies. In certain implementations, at least one of the semiconductor dies includes pins or pads protected using an electrical overstress (EOS) protection circuit. For example, an EOS protection circuit can include an overstress sensing circuit electrically connected between a pad of a semiconductor die and a first supply node, an impedance element electrically connected between the pad and a signal node, a controllable clamp electrically connected between the signal node and the first supply node and selectively activatable by the overstress sensing circuit, and an overshoot limiting circuit electrically connected between the signal node and a second supply node. The overstress sensing circuit activates the controllable clamp when an EOS event is detected at the pad. Thus, the EOS protection circuit is arranged to divert charge associated with the EOS event away from the signal node to provide EOS protection. Implementing a front end system in this manner can achieve enhanced EOS protection, lower static power dissipation, and/or a more compact chip layout. In certain implementations, the pad is an input pad that receives a control signal for controlling the power amplifier 5 and/or LNA 6.

In accordance with certain embodiments, the front end systems of FIGS. 1 and 2 can include RF shielding and/or RF isolation structures. For example, the front end systems 10 and 20 can be implemented as radio frequency modules that are partially shielded. Additionally, a shielding layer is included over a shielded portion of the radio frequency module and an unshielded portion of the radio frequency module is unshielded. The shielding layer can shield certain components of the front end system (for instance, the power amplifier 5 and/or LNA 6) and leave other components (for instance, the integrated antenna 11) unshielded.

In certain implementations, the front end systems of FIGS. 1 and 2 can include a laminated substrate including an antenna that is printed on a top layer and a ground plane for shielding on a layer underneath the top layer. Additionally, at least one electronic component of the front end systems can be disposed along a bottom layer of the laminate substrate, with solder bumps disposed around the electronic component and electrically connected to the ground plane. The solder bumps can attach the module to a carrier or directly to a system board. The electronic component can be surrounded by solder bumps, and the outside edges of the electronic component can have ground solder bumps that are connected to the ground plane by way of vias. Accordingly, a shielding structure can be completed when the module is placed onto a carrier or system board, and the shielding structure can serve as a Faraday cage around the electronic component.

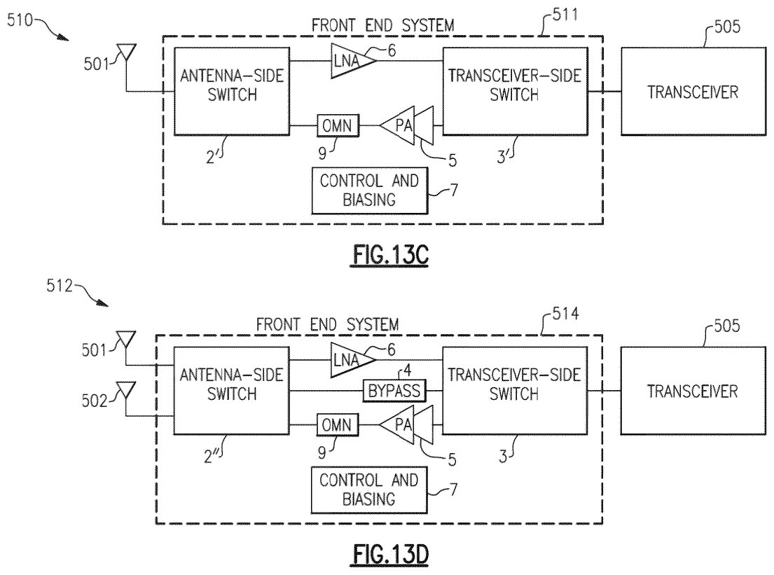

In certain embodiments, the front end systems disclosed herein are implemented on a semiconductor die as a front end integrated circuit (FEIC). The FEIC can be included in a packaged module (see, e.g., FIGS. 12A and 12B) that stacks multiple chips and passive components, such as capacitors and resistors, into a compact area on a package substrate. By implementing an FEIC in such a packaged module, a smaller footprint and/or a more compact substrate area can be achieved.

FIG. 3 illustrates a mobile device 30 such as a smartphone, tablet, etc. that includes a front end integrated circuit 10 in which front end components, such as amplifiers, output matching networks, switches, and a controller are all integrated on a single die. As shown in FIG. 3, semiconductor die 34 may be a silicon-on-insulator (SOI) die that includes one or more power amplifiers 5, each of which may include multiple stages of amplification, an output matching network 9, switches 12, such as antenna-side switches 2 and/or transceiver-side switches 20, and a controller (e.g., control and biasing circuitry 7 such as that depicted in FIGS. 1 and 2). Each of the components 5, 7, 9, and 12 may be implemented on a single SOI die 34, which is in turn, mounted to a substrate, for example a laminate 32, such as a PCB substrate. The laminate 32 may include additional devices, such as surface mount devices 36 (inductors, capacitors, resistors, etc. and other embedded devices 38 that may not be readily or desirably integrated on the SOI die 34). The laminate may itself form a module of the mobile device 30.

In accordance with certain embodiments, a packaged module includes a FEIC, a crystal oscillator, and a system on a chip (SoC), such as a transceiver die. The SoC can be stacked over a crystal assembly to save space and provide shorter crystal traces. The crystal assembly includes the crystal oscillator housed in a housing that includes one or more conductive pillars for routing signals from the SoC to a substrate and/or to provide thermal conductivity.

In accordance with certain embodiments, a packaged module includes a FEIC, a filter assembly, and a SoC. For example, the filter assembly can be stacked with other dies and components of the packaged module to reduce a footprint of the packaged module. Furthermore, stacking the filter assembly in this manner can reduce lengths of signal carrying conductors, thereby reducing parasitics and enhancing signaling performance.

A system in a package (SiP) can include integrated circuits and/or discrete components within a common package. Some or all of a front end system can be implemented in a SiP. An example SiP can include a system-on-a-chip (SoC), a crystal for clocking purposes, and a front-end module (FEM) that includes a front end system.

### Field-Effect Transistors (FETs)

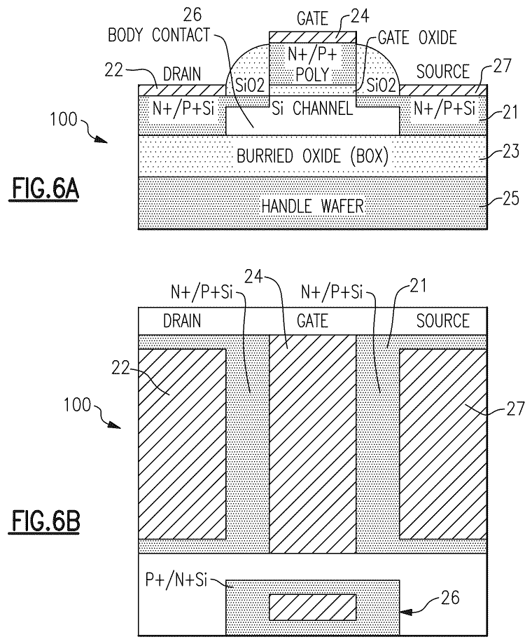

FIG. 4 illustrates an example field-effect transistor (FET) device 100 implemented as an individual silicon-on-insulator (SOI) unit. Such an individual SOI device can include one or more active FETs 101 implemented over an insulator such as a buried oxide (BOX) layer 104 which is itself implemented over a handle layer such as a silicon (Si) substrate handle wafer 106. In the example of FIG. 4, the BOX layer 104 and the Si substrate handle wafer 106 can collectively form a substrate 103. In the example of FIG. 4, the individual SOI device 100 is shown to further include an upper layer 107.

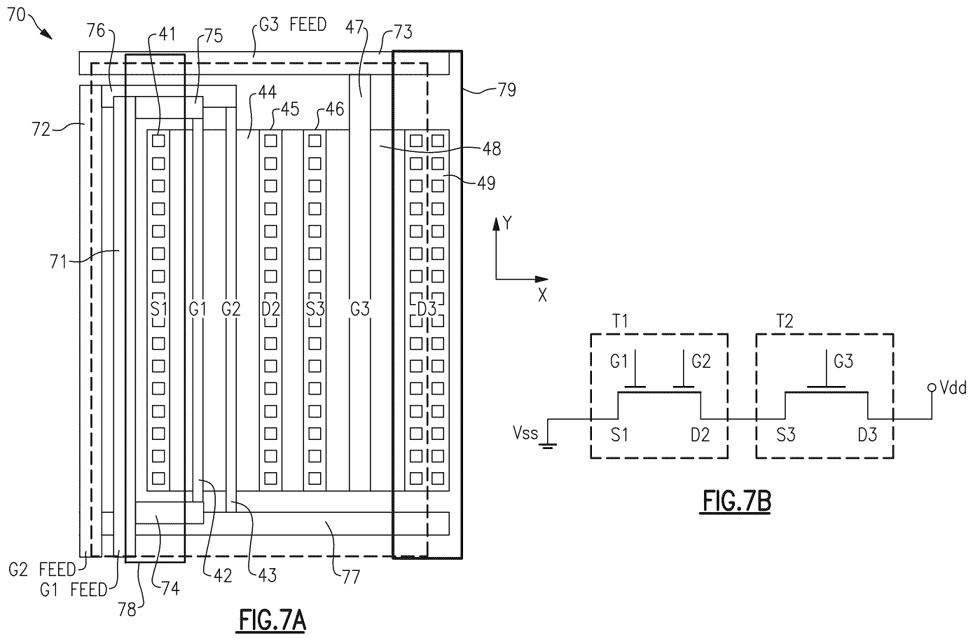

FIG. 5 illustrates that, in some embodiments, a plurality of individual SOI devices similar to the example SOI device 100 of FIG. 4 can be implemented on a wafer 200. As shown, such a wafer can include a wafer substrate 103 that includes a BOX layer 104 and a Si handle wafer layer 106 as described in reference to FIG. 4. As described herein, one or more active FETs can be implemented over such a wafer substrate. In the example of FIG. 5, the SOI device 100 is shown without the upper layer (107 in FIG. 4). It will be understood that such a layer can be formed over the wafer substrate 103, be part of a second wafer, or any combination thereof.

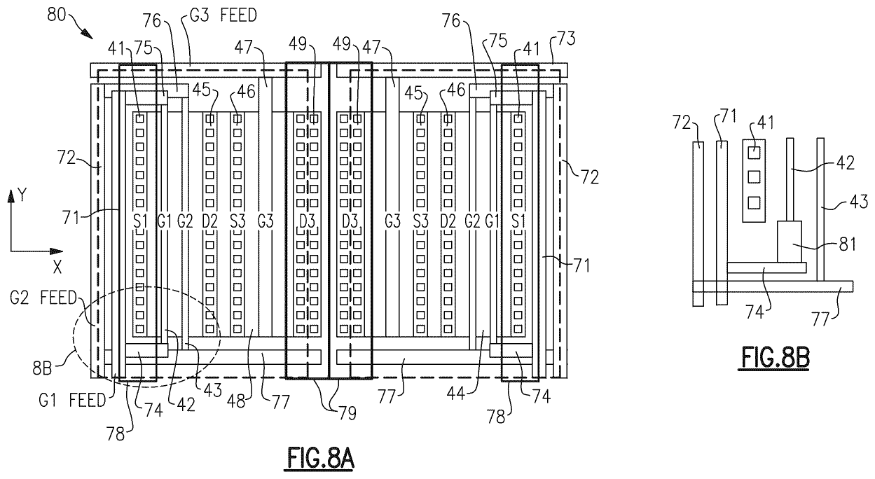

FIGS. 6A and 6B illustrate side sectional and plan views of an example SOI FET device 100 having an active FET implemented over a substrate such as a silicon substrate associated with a handle wafer 25. Although described in the context of such a handle wafer, it will be understood that the substrate does not necessarily need to have functionality associated with a handle wafer.

An insulator layer such as a BOX layer 23 is shown to be formed over the handle wafer 25, and the active FET is shown to be formed based on an active diffusion layer 21 over the BOX layer 23. The active diffusion layer 21 may be formed of silicon doped with various dopants in different dopant concentrations to achieve positively or negatively charged areas of desired degrees of impurities. In various examples described herein, and as shown in FIGS. 6A and 6B, the active FET can be configured as an NPN or PNP device.

The gate contact of the FET may formed by a gate oxide layer, a gate polysilicon layer deposited on the gate oxide layer, and a gate electrode 24 deposited on the gate polysilicon layer. In the example of FIGS. 6A and 6B, terminals for the gate electrode 24, source electrode 27, drain electrode 22 and body contact 26 are shown to be configured and provided to allow operation of the FET. It will be understood that in some embodiments, the source and the drain can be interchanged.

### Stacked Power Amplifier Designs

CMOS technology provides for a low-cost solution to integrate radiofrequency (RF), digital, and analog functions into a single chip. In front-end modules for RF communications, good performances have already been achieved for the switches and the low noise amplifiers using CMOS technologies. CMOS power amplifiers, however, due to their relatively low breakdown voltage and low power density, still present challenges for fully integrated front-end-module designs.

To alleviate the high voltage swing at the output, typically several transistors are connected in series in CMOS power amplifier designs so that a plurality of SOI FET devices can be implemented in a stack configuration. Stacking allows the limited breakdown voltage for each individual device to be overcome by proper alignment of their respective collector voltage waveforms. Due to layout parasitic effects, however, this alignment of the collector voltage waveforms becomes progressively more difficult to achieve as the number of stacked devices increases.

To deliver high power, a larger number of stacked power amplifier cells may be arranged in an array forming a stacked power amplifier array. Such stacked power amplifier arrays can become very large in lateral extent so that balancing the voltage among different units in the array has a large impact on the reliability and ruggedness of the resulting stacked power amplifier. To overcome the difficulties in voltage balancing of CMOS power amplifiers in a stacked power amplifier cell, a compact and well balanced cell design becomes important.

Disclosed herein are various examples and implementations of stacked power amplifier cells having a balanced power cell design which integrates FET devices with independent active diffusion regions and/or with different gate oxide thickness. Moreover, the stacked power amplifier cells disclosed herein may be arranged in arrays of multiple adjacent stacked power amplifier cells, electrically coupled together in series and/or parallel power amplifier stages. The arrays are therefore easily scalable in a compact and balanced layout. Such layouts may result in reduced parasitics and better thermal management. All of the disclosed examples and implementations of stacked power amplifier cells and the corresponding arrays thereof may be manufactured in silicon-on-insulator (SOI) technology as well as complementary metal-oxide semiconductor (CMOS) technology, with silicon or gallium nitride (GaN) substrates. Dies including any of those stacked power amplifier cells may be implemented in flip-chip (FC) design or with wirebonding.

FIG. 7A illustrates a top view of some layers in a stacked power amplifier cell 70 according to one embodiment. FIG. 7B shows the functional electric circuit equivalent of the stacked power amplifier cell 70 as illustrated in FIG. 7A. In the illustrative implementation of the stacked power amplifier cell 70, two SOI FET devices are arranged in series between two nodes. Such nodes can be utilized as input and output nodes. It will be understood, however, that any number of SOI FET devices can be utilized in a stack. For example, a stacked power amplifier cell may include more than two SOI FET devices arranged in series between the two nodes.

In the stacked power amplifier cell 70, a first SOI FET device T1 is implemented as a common-source (CS) transistor with source S1 and drain D2 in a cascode transistor configuration, while a second SOI FET device T2 is implemented as a common-gate (CG) transistor with source S3 and drain D3 in the cascode transistor configuration. The source S1 is connected to a ground potential Vss, while the drain D3 is connected to a supply potential Vdd. In the example configuration of FIGS. 7A and 7B, the first SOI FET device T1 is implemented with two gate contacts G1 and G2, while the second SOI FET device T2 is implemented with one gate contact G3. The number of gate contacts, however, is not limited thereto. In other implementations, it may be possible for the first SOI FET device T1 to be implemented with one gate contact only or with more than two gate contacts. Similarly, the second SOI FET device T2 may be implemented with any number of gate contacts. In some implementations, a plurality of first SOI FET devices T1 may be provided in a series connection, functioning together as a CS transistor in the cascade configuration. Furthermore, some implementations may include a plurality of second SOI FET devices T2 provided in a series connection, functioning together as a CG transistor in the cascode configuration.

The stacked power amplifier (PA) cell 70 of FIG. 7A includes a carrier substrate (not explicitly shown). The carrier substrate may for example be a silicon substrate or a gallium nitride (GaN) substrate. In some implementations, a buried oxide (BOX) layer may additionally be deposited on the carrier substrate. The carrier substrate alone or the carrier substrate together with the BOX layer may be referred to as a substrate, similar to the substrate 103 as illustrated in FIGS. 4 and 5. An active diffusion layer is deposited on the substrate. The active diffusion layer may be formed similarly to the active diffusion layer 21 as illustrated in FIGS. 6A and 6B.

In some embodiments, the active diffusion layer includes different active diffusion regions in sequence along a direction of the current flow through the SOI FET devices. In the illustration of FIG. 7A, this direction is denoted as the X-direction while the Y-direction is perpendicular to the X-direction in the plane of the substrate. For example, a first active diffusion region 44 is implemented underneath the source, gate, and drain contacts of the first SOI FET device T1. A second active diffusion region 48 is implemented underneath the source, gate, and drain contacts of the second SOI FET device T2. It should be understood that more active diffusion regions than the regions 44 and 48 may be formed in the active diffusion layer, depending on the number of series transistors in the stacked PA cell 70. In various implementations, the active diffusion regions 44 and 48 are manufactured independently from each other so that the first SOI FET device T1 and the second SOI FET device T2 do not have to share a uniform active diffusion layer.

On the active diffusion layer, the circuitry elements of the transistors T1 and T2 are formed. A first series transistor (for example, the first SOI FET device T1) is implemented with a first source electrode 41, a first drain electrode 45, and a first gate contact 42 mounted on the first active diffusion region 44. The first gate contact 42 includes a first gate oxide layer deposited on the first active diffusion region 44, a first gate polysilicon layer arranged on the first gate oxide layer, and a first gate electrode deposited on the first gate polysilicon layer. In particular, the first gate contact 42 may be implemented as illustrated in and explained in conjunction with FIG. 6A. Analogously, a second series transistor (for example, the second SOI FET device T2) is implemented with a second source electrode 46, a second drain electrode 49, and a second gate contact 47 mounted on the second active diffusion region 48. The second gate contact 47 includes a second gate oxide layer deposited on the second active diffusion region 48, a second gate polysilicon layer arranged on the second gate oxide layer, and a second gate electrode deposited on the second gate polysilicon layer. In particular, the second gate contact 47 may be implemented as illustrated in and explained in conjunction with FIG. 6A. To form a series connection of the two transistors the second source electrode 46 is electrically connected to the first drain electrode 45.

In some embodiments, the first series transistor includes a third gate contact 43 mounted on the first active diffusion region 44 adjacent to the first gate contact 42. Similarly to the first gate contact 42, the third gate contact 43 includes a third gate oxide layer deposited on the first active diffusion region 44, a third gate polysilicon layer arranged on the third gate oxide layer, and a third gate electrode deposited on the third gate polysilicon layer. In particular, the third gate contact 43 may be implemented as illustrated in and explained in conjunction with FIG. 6A. In various implementations, the third gate contact 43 may share the gate polysilicon layer and gate oxide layer with the first gate contact 42. Alternatively, it may be possible to form the third gate polysilicon layer separately from the first gate polysilicon layer and the third gate oxide layer separately from the first gate oxide layer.

The source electrodes 41 and 46 and the drain electrodes 45 and 49 may be formed in the same metallization layer over the active diffusion layer. The gate electrodes of the gate contacts 42, 43, and 47 may be formed in a different metallization layer than the metallization layer(s) of the source electrodes 41 and 46 and the drain electrodes 45 and 49. A source contact metallization layer 78 may be formed over the first source electrode 41 to provide for a solid contact to a ground potential Vss. Additionally, a redistribution layer (not explicitly shown in FIG. 7A) may be formed over the source contact metallization layer 78 for more flexible routing to ground.

Similarly, a drain contact metallization layer 79 may be formed over the second drain electrode 49. The drain contact metallization layer 79 is used to electrically connect the second drain electrode 49 to a supply potential Vdd. The drain contact metallization layer 79 may be formed in the same metallization layer level as the source contact metallization layer 78.

To achieve a compact, well-balanced cell design for a stacked power amplifier, the thicknesses of the first gate oxide layer and the second gate oxide layer may be different. In particular, a thickness of the second gate oxide layer may be greater than a thickness of the first gate oxide layer so that the terminal voltages of the second transistor T2 may be increased in comparison to the first transistor T1. Additionally or alternatively, the thicknesses of the first active diffusion region 44 and the second active diffusion region 48 may be different as well. In particular, a thickness of the second active diffusion region 48 may be greater than a thickness of the first active diffusion region 44.

Still referring to FIG. 7A, the stacked PA cell 70 includes a first gate feed strip 71 deposited on the substrate and electrically connected to the first gate electrode 42. In the illustrated example, the first gate electrode 42 is a thin metallization extending in the Y-direction perpendicular to the current flow direction through the cascade configuration of the transistors T1 and T2. The first gate feed strip 71 extends in parallel to the first gate electrode 42. The first gate feed strip 71 may have two first gate feed connections 74 and 75 above and below the active diffusion layer for a more uniform gate contact to reduce series inductance, and to mitigate voltage imbalance under RF conditions.

Similarly, a second gate feed strip 72 is deposited on the substrate and electrically connected to the third gate electrode 43. The second gate feed strip 72 may be connected to the third gate electrode 43 via two second gate feed connections 76 and 77 above and below the active diffusion layer. One of the second gate feed connections (second gate feed connection 77 in FIG. 7A) may extend in the X-direction over the entire stacked PA cell 70, and possibly beyond, to connect all of the third gate electrodes 43 of neighboring PA cells more uniformly and with little series inductance. A third gate feed strip 73 is deposited on the substrate and electrically connected to the second gate electrode 47. The third gate feed strip 73 runs perpendicular to the second gate electrode 47, i.e., in the X-direction in the illustration of FIG. 7A.

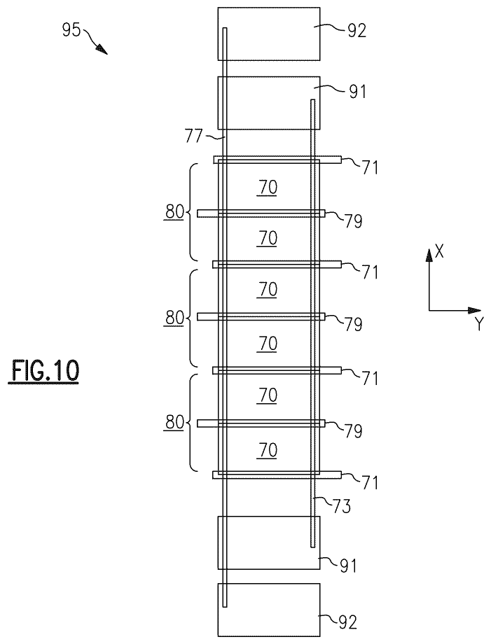

FIG. 8A illustrates a top view of some layers in a stacked power amplifier (PA) cell 80 according to another embodiment. The stacked PA cell 80 is similar to the stacked PA cell 70 of FIG. 7A, except that two of the stacked PA cells 70 are placed next to each other in the X-direction with the sequence of circuitry elements and layers reversed in the X-direction. In other words, the sequence of transistors and transistor elements in the left half of the stacked PA cell 80 is opposite to the sequence of transistors and transistor elements in the right half of the stacked PA cell 80. With this design, a common drain contact metallization layer 79 formed over both of the second drain electrodes 49 in the middle of the stacked PA cell 80 may be realized for increased power density. Moreover, the common drain contact metallization layer 79 runs in parallel to the first gate feed strips 71 on the left and the right of the stacked PA cell 80, but at a maximum distance from each other.

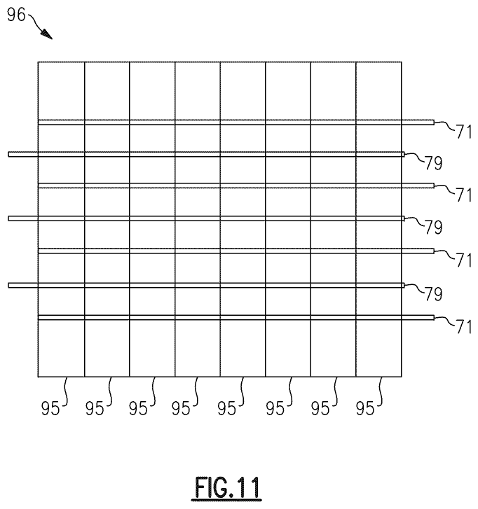

FIG. 9 illustrates a top view of some layers in an array 90 of stacked PA cells. The array 90 may be formed by placing two of the stacked PA cells 80 as illustrated in FIG. 8A next to each other in the Y-direction. The first gate feed strips 71 as well as the common drain contact metallization layers 79 may advantageously be connected to each other over the boundaries of the stacked PA cells 80.

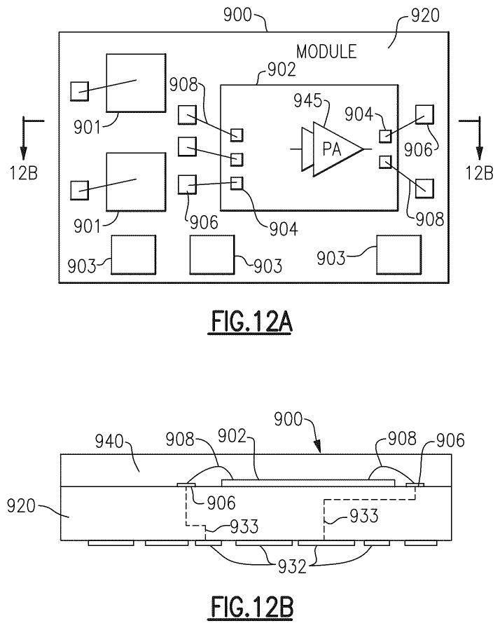

FIG. 10 shows a simplified illustration of another array 95 of stacked power amplifier (PA) cells 80 according to the arrangement of FIG. 8A. In the illustrative example of FIG. 10, the array 95 has a linear sequence of three stacked PA cells 80 arranged along the X-direction. Each of the three stacked PA cells 80 includes two of the stacked PA cells 70 as shown in FIG. 7A with the sequence of circuitry elements and layers reversed in the X-direction. As can be seen from FIG. 10, a number or first gate feed strips 71 run in parallel to the edges of the stacked PA cells 80 in the Y-direction, while the common drain contact metallization layers 79 run in parallel to the first gate feed strips 71 in the Y-direction, but spaced apart from the first gate feed strips 71 in the X-direction. This ensures that the drain contacts and the first gate contacts of each of the stacked PA cells 70 are isolated from each other as well as possible so that parasitic coupling between them is minimized.

The second gate feed strip 77 and the third gate feed strip 73 run in the X-direction perpendicular to the first gate feed strip 71 and the drain contact metallization layers 79. At the ends of the array 95, integrated gate capacitors may be implemented to decouple the gate contacts. For example, two first gate capacitors 92 may be connected to the second gate feed strip 77 at either end of the array 95. Similarly, two second gate capacitors 91 may be connected to the third gate feed strip 73 at either end of the array 95. The first and second gate capacitors 91 and 92 may be integrated adjacent to each other in the X-direction. Through-oxide substrate contacts may be utilized to couple the first and second gate capacitors 91 and 92 to ground for improved thermal conduction. Integrating such gate capacitors in proximity to the stacked PA cells 80 aids in enhancing the quality factor (Q), the bandwidth performance and the characteristics at higher frequencies. Moreover, thermal management of the array 95 becomes easier due to the improved grounding and thus improved thermal conduction.

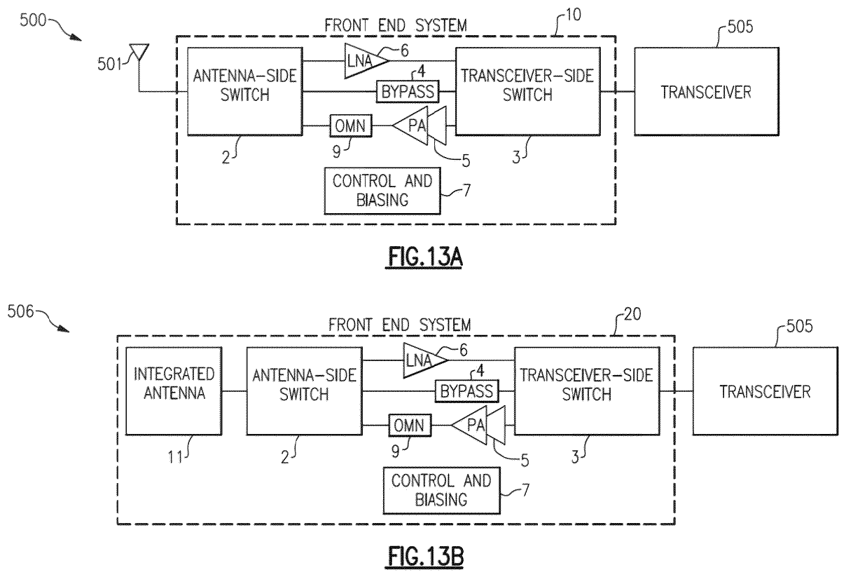

FIG. 11 shows a simplified illustration of an array 96 of stacked PA cells according to yet another embodiment. The array 96 may be formed by placing a number of arrays 95 as illustrated in FIG. 10 next to each other. The first gate feed strips 71 and the common drain contact metallization layers 79 may then be coupled over neighboring arrays 95. The design of array 96 ensures a compact and highly scalable layout of a large number of stacked PA cells 70.

Referring back to FIG. 8A, a possible variation of the implementation in the dotted circle labelled with 8B is shown in FIG. 8B. Between the gate feed connection 74 and the first gate electrode 42 a resistor 81 may be integrated onto the substrate. Such an integrated resistor 81 aids in providing improved stability.

### Packaged Modules

FIG. 12A is a schematic diagram of one embodiment of a packaged module 900 which can incorporate any of the front end systems described herein or otherwise be incorporated into any of the mobile devices included herein. For example, the module 900 may correspond to the module 32 of FIG. 3. FIG. 12B is a schematic diagram of a cross-section of the packaged module 900 of FIG. 12A taken along the lines 12B-12B.

The packaged module 900 includes radio frequency components 901, a semiconductor die 902, surface mount devices 903, wirebonds 908, a package substrate 920, and an encapsulation structure 940. For example, the semiconductor die 902 can be the semiconductor die 34 of FIG. 3, and can incorporate the front end system 10 of FIG. 1, or the front end system 20 of FIG. 2. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a power amplifier 945, which can be implemented in accordance with one or more features disclosed herein. While only the power amplifier 945 is shown for simplicity, it will be appreciated that additional componentry including any of the output matching networks, LNAs, switches, controllers, and the like can be included.

The packaging substrate 920 can be configured to receive a plurality of components such as radio frequency components 901, the semiconductor die 902, and the surface mount devices 903, which can include, for example, surface mount capacitors and/or inductors. In one implementation, the radio frequency components 901 include integrated passive devices (IPDs).

As shown in FIG. 12B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 12B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### Radio Frequency Systems

FIGS. 13A to 13D illustrate various schematic block diagrams of examples of radio frequency systems that include a front end system, such as a front end module (FEM) or front end integrated circuit (FEIC). The radio frequency systems of FIGS. 13A to 13D can incorporate one or more features described in the sections herein. In certain implementations, a radio frequency system, such as any of the radio frequency systems of FIGS. 13A to 13D, is implemented on a circuit board (for instance, a printed circuit board (PCB)) of a wireless communication device, such as a mobile phone, a tablet, a base station, a network access point, customer-premises equipment (CPE), an IoT-enabled object, a laptop, and/or a wearable electronic device.

FIG. 13A illustrates a schematic block diagram of one example of a radio frequency system 500. The radio frequency system 500 includes an antenna 501, a front end system 10, and a transceiver 505. As was discussed above, the front end system 10 can incorporate one or more features described in the sections herein.

The antenna 501 operates to wirelessly transmit RF signals received via the antenna-side switch 2. The RF transmit signals can include RF signals generated by the power amplifier 5 and/or RF signals sent via the bypass circuit 4. The output matching network 9 receives the signal generated by the power amplifier 5. The antenna 501 also operates to wirelessly receive RF signals, which can be provided to the LNA 6 and/or the bypass circuit 4 via the antenna-side switch 2. Although an example where a common antenna is used for transmitting and receiving signals, the teachings herein are also applicable to implementations using separate antennas for transmission and reception. Example implementations of the antenna 501 include, but are not limited to, a patch antenna, a dipole antenna, a ceramic resonator, a stamped metal antenna, a laser direct structuring antenna, and/or a multi-layered antenna.

The transceiver 505 operates to provide RF signals to the transceiver-side switch 3 for transmission and/or to receive RF signals from the transceiver-side switch 3. The transceiver 505 can communicate using a wide variety of communication technologies, including, but not limited to, one or more of 2G, 3G, 4G (including LTE, LTE-Advanced, and/or LTE-Advanced Pro), 5G, WLAN (for instance, Wi-Fi), WPAN (for instance, LTE-M, Bluetooth and/or ZigBee), WMAN (for instance, WiMAX), and/or GPS technologies.

FIG. 13B illustrates a schematic block diagram of another example of a radio frequency system 506. The radio frequency system 506 includes a front end system 20 and a transceiver 505. As was discussed above, the front end system 20 can incorporate one or more features described in the sections herein.

FIG. 13C illustrates a schematic block diagram of another example of a radio frequency system 510. The radio frequency system 510 includes an antenna 501, a front end system 511, and a transceiver 505. The front end system 511 of FIG. 13C is similar to the front end system 10 of FIG. 13A, except that the bypass path including the bypass circuit 4 has been omitted and the antenna-side switch 2′ and the transceiver-side switch 3′ include one less throw. Thus, the antenna-side switch 2′ is configured to selectively electrically connect the antenna 501 to either an input to the LNA 6 or an output of the power amplifier 5. Additionally, the transceiver-side switch 3′ is configured to selectively electrically connect the transceiver 505 to either an output to the LNA 6 or an input of the power amplifier 5.

FIG. 13D illustrates a schematic block diagram of another example of a radio frequency system 512. The radio frequency system 512 includes a first antenna 501, a second antenna 502, a front end system 514, and a transceiver 505. The front end system 514 of FIG. 13D is similar to the front end system 10 of FIG. 13A, except that the antenna-side switch 2″ includes an additional throw to provide connectivity to an additional antenna. Thus, the bypass circuit 4, the power amplifier 5, and/or the LNA 6 can be selectively electrically connected to the first antenna 501 and/or the second antenna 502. Although an example of a radio frequency system with two antennas is shown, a radio frequency system can include more or fewer antennas.

The front end systems 10, 20, 511, 514 of FIGS. 13A to 13D can incorporate any of the front end systems described herein, such as those described with respect to FIGS. 1, 2, and 3, or any of the corresponding circuitry such as any of the output matching networks 9 of those front end systems. More particularly, some or all of front end systems 10, 20, 511, 514 of FIGS. 13A to 13D can include stacked power cell arrays as illustrated in and described in conjunction with FIGS. 7A, 7B, 8A, 8B, 9, 10, or 11.

Multiple antennas can be included in a radio frequency system for a wide variety of reasons. In one example, the first antenna 501 and the second antenna 502 correspond to a transmit antenna and a receive antenna, respectively. In a second example, the first antenna 501 and the second antenna 502 are used for transmitting and/or receiving signals associated with different frequency ranges (for instance, different bands). In a third example, the first antenna 501 and the second antenna 502 support diversity communications, such as multiple-input multiple-output (MIMO) communications and/or switched diversity communications. In a fourth example, the first antenna 501 and the second antenna 502 support beamforming of transmit and/or receive signal beams.

### Wireless Communication Devices

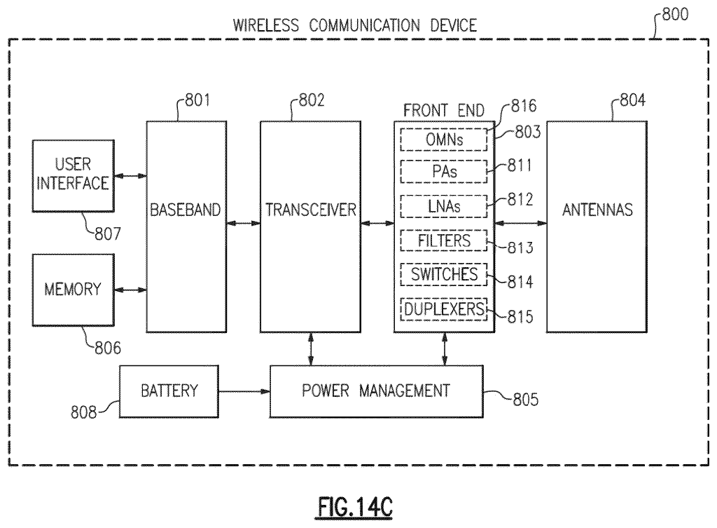

FIG. 14A is a schematic diagram of one example of a wireless communication device 650. The wireless communication device 650 includes a first antenna 641, a wireless personal area network (WPAN) system 651, a transceiver 652, a processor 653, a memory 654, a power management block 655, a second antenna 656, and a front end system 657.

Any of the suitable combination of features disclosed herein can be implemented in the wireless communication device 650. For example, the WPAN system 651 and/or the front end system 657 can be implemented using any of the features described above and/or in the sections below.

The WPAN system 651 is a front end system configured for processing radio frequency signals associated with personal area networks (PANs). The WPAN system 651 can be configured to transmit and receive signals associated with one or more WPAN communication standards, such as signals associated with one or more of LTE-M (LTE Machine Type Communication), Bluetooth, ZigBee, Z-Wave, Wireless USB, INSTEON, IrDA, or Body Area Network. In another embodiment, a wireless communication device can include a wireless local area network (WLAN) system in place of the illustrated WPAN system, and the WLAN system can process Wi-Fi signals.

FIG. 14B is a schematic diagram of another example of a wireless communication device 660. The illustrated wireless communication device 660 of FIG. 14B is a device configured to communicate over a PAN. This wireless communication device 660 can be relatively less complex than the wireless communication device 650 of FIG. 14A. As illustrated, the wireless communication device 660 includes an antenna 641, a WPAN system 651, a transceiver 662, a processor 653, and a memory 654. The WPAN system 660 can include any suitable combination of features disclosed herein. For example, the WPAN system 651 can be implemented using any of the features described above and/or in the sections below.

FIG. 14C is a schematic diagram of another example of a wireless communication device 800. The wireless communication device 800 includes a baseband system 801, a transceiver 802, a front-end system 803, one or more antennas 804, a power management system 805, a memory 806, a user interface 807, and a battery 808.

The wireless communication device 800 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, LTE-M, Bluetooth and ZigBee), WMAN (for instance, WiMAX), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 14C as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes one or more power amplifiers (PAs) 811, one or more low noise amplifiers (LNAs) 812, one or more filters 813, one or more switches 814, and one or more duplexers 815, and one or more output matching networks 816. However, other implementations are possible.

For example, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

Any of the suitable combination of features disclosed herein can be implemented in the wireless communication device 800. For example, the front end system 803 can be implemented using any of the features described above and/or in the sections below.

In certain implementations, the wireless communication device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate (BER) and/or a received signal strength indicator (RSSI).

The wireless communication device 800 can operate with beamforming in certain implementations. For example, the front-end system 803 can include phase shifters having variable phase controlled by the transceiver 802. Additionally, the phase shifters are controlled to provide beam formation and directivity for transmission and/or reception of signals using the antennas 804. For example, in the context of signal transmission, the phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 14C, the baseband system 801 is coupled to the memory 806 of facilitate operation of the wireless communication device 800.

The memory 806 can be used for a wide variety of purposes, such as storing data and/or instructions to facilitate the operation of the wireless communication device 800 and/or to provide storage of user information.

The power management system 805 provides a number of power management functions of the wireless communication device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 14C, the power management system 805 receives a battery voltage from the battery 808. The battery 808 can be any suitable battery for use in the wireless communication device 800, including, for example, a lithium-ion battery.

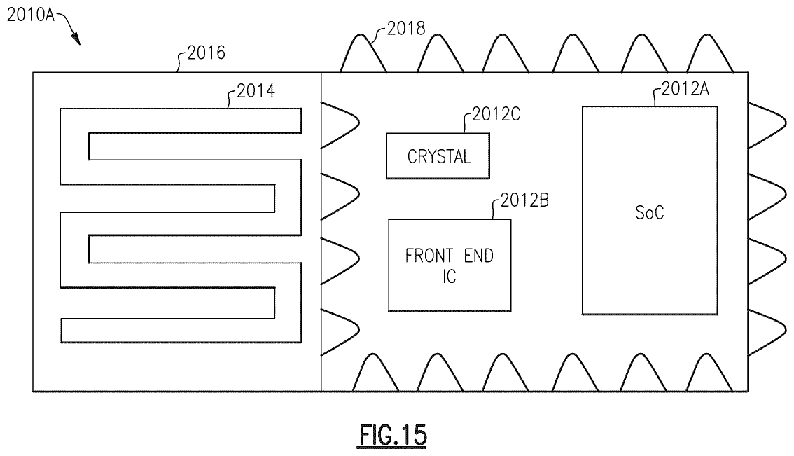

Some or all of the front end systems 657, 803 or WPAN systems 651 of FIGS. 14A to 14C can incorporate any of the front end systems described herein, such as those described with respect to FIGS. 1, 2, or 3, or any of the corresponding circuitry such as any of the output matching networks 9 of those front end systems. More particularly, some or all of the front end systems 657, 803 or WPAN systems 651 of FIGS. 14A to 14C can include stacked power cell arrays as illustrated in and described in conjunction with FIGS. 7A, 7B, 8A, 8B, 9, 10, or 11. FIG. 15 is a schematic diagram of an example RF module 2010A that includes a system-on-chip 2012A, an RF front end IC 2012B, a crystal 2012C, and an integrated antenna 2014 according to an embodiment. The system-on-chip 2012A can include one or more of a transceiver, processor (e.g., a baseband processor), and memory. The RF front end IC 2012B can include any of the front end components described herein, such as any of the front end systems of FIGS. 1, 2, or 3. For example, the RF front end IC 2012B can include, for example, any of the power amplifiers, switches, low noise amplifiers, and output matching networks described herein. In some embodiments, the RF front end IC 2012B is a semiconductor-on-insulator (e.g., silicon-on-insulator) die implementing FET-based stacked power cells as illustrated in and explained in conjunction with FIGS. 7A, 7B, 8A, 8B, 9, 10, or 11. The RF module 2010A can be a system in a package.

FIG. 15 shows the RF module 2010A in plan view without a top shielding layer, which can also be included. As illustrated, the RF module 2010A includes the components 2012A-2012C on a package substrate 2016, the antenna 2014 on the package substrate 2016, and wire bonds 2018 attached to the package substrate 2016 and surrounding the components 2012A-2012C. The antenna 2014 of the RF module 2010A is outside of an RF shielding structure around the components 2012A-2012C. Accordingly, the antenna 2014 can wirelessly receive and/or transmit RF signals without being shielded by the shielding structure around the components 2012A-2012C. At the same time, the shielding structure can provide RF isolation between the components 2012A-2012C and the antenna 2014 and/or other electronic components.

The components 2012A-2012C can include any suitable circuitry configured to receive, process, and/or provide an RF signal. In certain implementations, the RF front end IC 2012B can include a power amplifier, a low-noise amplifier, an RF switch, a filter, a matching network, or any combination thereof, and can be clocked by a signal derived from the crystal 2012C. An RF signal can have a frequency in the range from about 30 kHz to 300 GHz. In accordance with certain communications standards, an RF signal can be in a range from about 450 MHz to about 7.125 GHz, in a range from about 700 MHz to about 2.5 GHz, or in a range from about 2.4 GHz to about 2.5 GHz. In certain implementations, the RF module 2010A can receive and/or provide signals in accordance with a wireless personal area network (WPAN) standard, such as LTE-M, Bluetooth, ZigBee, Z-Wave, Wireless USB, INSTEON, IrDA, or Body Area Network. In some other implementations, the RF module can receive and/or provide signals in accordance with a wireless local area network (WLAN) standard, such as Wi-Fi.

The antenna 2014 can be any suitable antenna configured to receive and/or transmit RF signals. The antenna 2014 can be a folded monopole antenna in certain implementations. The antenna 2014 can be any suitable shape. For instance, the antenna 2014 can have a meandering shape as shown in FIG. 15. In other embodiments, the antenna can be U-shaped, coil shaped, or any other suitable shape for a particular application. The antenna 2014 can transmit and/or receive RF signals associated with the RF front end IC 2012B. The antenna 2014 can occupy any suitable amount of area of the packaging substrate 2016. For instance, the antenna 2014 can occupy from about 10% to 75% of the area of the package substrate 2016 in certain implementations.

The antenna 2014 can be printed on the packaging substrate 2016. A printed antenna can be formed from one or more conductive traces on the packaging substrate 2016. The one or more conductive traces can be formed by etching a metal pattern on the packaging substrate 2016. A printed antenna can be a microstrip antenna. Printed antennas can be manufactured relatively inexpensively and compactly due to, for example, their 2-dimensional physical geometries. Printed antennas can have a relatively high mechanical durability.

The package substrate 2016 can be a laminate substrate. The package substrate 2016 can include one or more routing layers, one or more insulating layers, a ground plane, or any combination thereof. In certain applications, the package substrate can include four layers. The RF front end IC 2012B can be electrically connected to the antenna 2014 by way of metal routing in a routing layer of the packaging substrate 2016 in certain applications.

The wire bonds 2018 are part of an RF shielding structure around the components 2012A-2012C. An RF shielding structure can be any shielding structure configured to provide suitable shielding associated with RF signals. The wire bonds 2018 can provide RF isolation between the antenna 2014 and some or all of the components 2012A-2012C so as to prevent electromagnetic interference between these components from significantly impacting performance of the antenna 2014 and/or some or all of the components 2012A-2012C. The wire bonds 2018 can surround the components 2012A-2012C as illustrated. The wire bonds 2018 can be arranged around the components 2012A-2012C in any suitable arrangement, which can be rectangular as illustrated or non-rectangular in some other implementations. In the RF module 2010A illustrated in FIG. 15, the wire bonds 2018 form four walls around the components 2012A-2012C. The wire bonds 2018 can be arranged such that adjacent wire bonds are spaced apart from each other by a distance to provide sufficient RF isolation between the components 2012A-2012C and other electronic components.

FIG. 15 illustrates an RF module in accordance with the principles and advantages discussed herein. The RF module can be selectively shielded, where various RF components can be implemented within a shielding structure. For instance, FIG. 15 shows an example of an RF component that includes three different elements. Other RF components can alternatively or additionally be implemented. A conformal layer can be disposed along at least one side the RF component of the RF module in embodiments in which a shielding layer is formed after singulation of the RF modules. The conformal structure can include any suitable conductive material. For example, the conductive conformal structure can include the same conductive material as the shielding layer in certain implementations.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 25 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to. ” Conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel filters, devices, modules, radio frequency systems, wireless communication devices, apparatus, methods, and systems described herein may be embodied in a variety of other forms. Furthermore, various omissions, substitutions and changes in the form of the filters, multiplexer, devices, modules, radio frequency systems, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A stacked power amplifier cell, comprising:
a substrate;
an active diffusion layer deposited on the substrate;
a first series transistor including a first source electrode, a first drain electrode, and a first gate contact mounted on the active diffusion layer, the first gate contact including a first gate oxide layer deposited on the active diffusion layer, a first gate polysilicon layer arranged on the first gate oxide layer, and a first gate electrode deposited on the first gate polysilicon layer; and
a second series transistor including a second source electrode, a second drain electrode, and a second gate contact mounted on the active diffusion layer, the second gate contact including a second gate oxide layer deposited on the active diffusion layer, a second gate polysilicon layer arranged on the second gate oxide layer, and a second gate electrode deposited on the second gate polysilicon layer, the second source electrode being electrically connected to the first drain electrode and a thickness of the second gate oxide layer being greater than a thickness of the first gate oxide layer.

2. The stacked power amplifier cell of claim 1 wherein the first source electrode is electrically connected to a ground potential and the second drain electrode is electrically connected to a supply potential.

3. The stacked power amplifier cell of claim 1 further comprising a first gate feed strip deposited on the substrate and electrically connected to the first gate electrode, the first gate feed strip extending in parallel to the first gate electrode.

4. The stacked power amplifier cell of claim 3 further comprising an integrated resistor coupled between the first gate electrode and the first gate feed strip.

5. The stacked power amplifier cell of claim 3 further comprising a drain contact metallization layer formed over the second drain electrode, the drain contact metallization layer extending in parallel to the first gate feed strip.

6. The stacked power amplifier cell of claim 1 wherein the first series transistor includes a third gate contact mounted on the active diffusion layer adjacent to the first gate contact, the third gate contact including a third gate oxide layer deposited on the active diffusion layer, a third gate polysilicon layer arranged on the third gate oxide layer, and a third gate electrode deposited on the third gate polysilicon layer.

7. The stacked power amplifier cell of claim 6 wherein a thickness of the third gate oxide layer is substantially equal to the thickness of the first gate oxide layer.

8. The stacked power amplifier cell of claim 6 further comprising a second gate feed strip deposited on the substrate and electrically connected to the third gate electrode, the second gate feed strip extending perpendicular to the third gate electrode.

9. The stacked power amplifier cell of claim 1 further comprising a source contact metallization layer formed over the first source electrode, the source contact metallization layer being connected to ground potential.

10. A stacked power amplifier cell, comprising:
a substrate;
an active diffusion layer deposited on the substrate, the active diffusion layer including a first active diffusion region having a first thickness and a second active diffusion region having a second thickness, the second thickness being greater than the first thickness;
a first series transistor including a first source electrode, a first drain electrode, and a first gate contact mounted on the first active diffusion region, the first gate contact including a first gate oxide layer deposited on the first active diffusion region, a first gate polysilicon layer arranged on the first gate oxide layer, and a first gate electrode deposited on the first gate polysilicon layer; and
a second series transistor including a second source electrode, a second drain electrode, and a second gate contact mounted on the second active diffusion region, the second gate contact including a second gate oxide layer deposited on the second active diffusion region, a second gate polysilicon layer arranged on the second gate oxide layer, and a second gate electrode deposited on the second gate polysilicon layer, the second source electrode being electrically connected to the first drain electrode.

11. The stacked power amplifier cell of claim 10 wherein the first source electrode is electrically connected to a ground potential and the second drain electrode is electrically connected to a supply potential.

12. The stacked power amplifier cell of claim 10 further comprising a first gate feed strip deposited on the substrate and electrically connected to the first gate electrode, the first gate feed strip extending in parallel to the first gate electrode.

13. The stacked power amplifier cell of claim 12 further comprising an integrated resistor coupled between the first gate electrode and the first gate feed strip.

14. The stacked power amplifier cell of claim 12 further comprising a drain contact metallization layer formed over the second drain electrode, the drain contact metallization layer extending in parallel to the first gate feed strip.

15. The stacked power amplifier cell of claim 10 wherein the first series transistor includes a third gate contact mounted on the first active diffusion region adjacent to the first gate contact, the third gate contact including a third gate oxide layer deposited on the first active diffusion region, a third gate polysilicon layer arranged on the third gate oxide layer, and a third gate electrode deposited on the third gate polysilicon layer.

16. The stacked power amplifier cell of claim 15 further comprising a second gate feed strip deposited on the substrate and electrically connected to the third gate electrode, the second gate feed strip extending perpendicular to the third gate electrode.

17. The stacked power amplifier cell of claim 10 further comprising a source contact metallization layer formed over the first source electrode, the source contact metallization layer being connected to ground potential.

18. A radio-frequency (RF) module, comprising:
a packaging substrate configured to receive a plurality of components; and
a power amplification system implemented on the packaging substrate, the power amplification system including a stacked power amplifier (PA) cell configured to receive and amplify an RF signal, the stacked PA cell including a substrate, an active diffusion layer deposited on the substrate, a first series transistor including a first source electrode, a first drain electrode, and a first gate contact mounted on the active diffusion layer, the first gate contact including a first gate oxide layer deposited on the active diffusion layer, a first gate polysilicon layer arranged on the first gate oxide layer, and a first gate electrode deposited on the first gate polysilicon layer, and a second series transistor including a second source electrode, a second drain electrode, and a second gate contact mounted on the active diffusion layer, the second gate contact including a second gate oxide layer deposited on the active diffusion layer, a second gate polysilicon layer arranged on the second gate oxide layer, and a second gate electrode deposited on the second gate polysilicon layer, the second source electrode being electrically connected to the first drain electrode and a thickness of the second gate oxide layer being greater than a thickness of the first gate oxide layer.

19. The RF module of claim 18 wherein the first source electrode is electrically connected to a ground potential and the second drain electrode is electrically connected to a supply potential.

20. The RF module of claim 18 wherein the stacked PA cell further includes a first gate feed strip deposited on the substrate and electrically connected to the first gate electrode, the first gate feed strip extending in parallel to the first gate electrode.
